(19) United States
(12) Patent Application Publication
(10) Pub. No.: US 2025/0234487 A1
(43) Pub. Date: Jul. 17, 2025

(54) Heat dissipation control system, method and immersion liquid cooling system

(71) Applicant: BITMAIN TECHNOLOGIES INC., Beijing (CN)

(72) Inventors: Tianhao LI, Beijing (CN); Zesen NIE, Beijing (CN); Hangkong HU, Beijing (CN); Fengjie LI, Beijing (CN); Xiaoxiong ZHANG, Beijing (CN); Shaoming HUANG, Beijing (CN); Hongshan ZHU, Beijing (CN)

(21) Appl. No.: 19/017,047

(22) Filed: Jan. 10, 2025

(30) Foreign Application Priority Data
Jan. 12, 2024 (CN) 202410052251.8

(51) Int. Cl. H05K 7/20

(52) U.S. Cl. CPC H05K 7/20281; H05K 7/20236

(57) ABSTRACT

A heat dissipation control system, a heat dissipation method, and an immersion liquid cooling system are provided. The heat dissipation control system includes a radiator, a circulation pump, a fan, dry coolers, a temperature sensor, a first and a second variable-frequency drivers, and a heat dissipation controller. The temperature sensor is used for collecting a secondary-side liquid supply temperature. The heat dissipation controller is used for generating a control signal for the first and the second variable-frequency drivers based on a difference value between the secondary-side liquid supply temperature and a preset temperature. The first variable-frequency driver is used for controlling a frequency of the circulation pump so as to adjust a flow rate of a coolant flowing into the radiator. The second variable-frequency driver is used for activating or deactivating at least one of the dry coolers, and controlling a frequency of the fan.

### CROSS-REFERENCE TO RELATED APPLICATIONS

The present application claims priority to Chinese Patent Application No. 202410052251.8, filed on Jan. 12, 2024, which is hereby incorporated by reference in its entirety.

### TECHNICAL FIELD

The present application relates to the field of immersion liquid cooling technologies and, in particular, to a heat dissipation control system, a heat dissipation control method and an immersion liquid cooling system.

### BACKGROUND

An immersion liquid cooling system implements heat dissipation of a heating element (such as a server) in an immersion tank, by means of natural convection or a pump-driving coolant circulation.

A coolant distribution unit (CDU) is an important component of the immersion liquid cooling system that performs heat dissipation with a driving manner. The CDU uses liquid-cooling heat exchange to cool the heating element, enabling a colder coolant to flow into the tank under the drive of a circulation pump, thereby implementing heat dissipation for the heating element. The coolant heated by the heating element performs heat dissipation through a radiator or a heat exchanger, and then continues to circulate into the tank under the action of the circulation pump. A conventional immersion liquid cooling system mainly implements temperature control of a coolant in the tank by controlling a heat exchange amount of the CDU, and it has a single control variable, thus an adjustment range of temperature control is narrow, and an application range is limited.

Therefore, there is an urgent need to provide a heat dissipation control solution for the immersion liquid cooling system with a wide temperature control range.

### SUMMARY

The present application provides a heat dissipation control system, a heat dissipation control method, and an immersion liquid cooling system. A temperature of a coolant in the immersion liquid cooling system is jointly controlled by controlling a primary-side flow rate and a frequency of a fan of a dry cooler, thereby providing a wide temperature adjustment range and a strong environmental adaptability.

According to a first aspect, the present application provides a heat dissipation control system, applied to an immersion tank. The heat dissipation control system includes: a radiator, a circulation pump, a fan, dry coolers, a temperature sensor, a first variable-frequency driver, a second variable-frequency driver, and a heat dissipation controller.

The temperature sensor is used for collecting a secondary-side liquid supply temperature. The heat dissipation controller is used for generating a control signal for the first variable-frequency driver and the second variable-frequency driver, based on a difference value between the secondary-side liquid supply temperature and a preset temperature. The first variable-frequency driver is used for controlling a frequency of the circulation pump based on an input control signal, so as to adjust a flow rate of a coolant flowing into the radiator. The second variable-frequency driver is used for activating or deactivating at least one of the dry coolers based on an input control signal, and controlling a frequency of the fan, so as to adjust the number of at least one activated dry cooler or adjust a heat dissipation amount of the at least one activated dry cooler.

In a possible implementation, there are multiple temperature sensors, and the heat dissipation controller is specifically configured to:
generate the control signal for the first variable-frequency driver and the second variable-frequency driver based on a difference value between a maximum value among secondary-side liquid supply temperatures collected by the multiple temperature sensors and the preset temperature.

In a possible implementation, the heat dissipation controller is specifically configured to:
when the secondary-side liquid supply temperature or a maximum value among multiple secondary-side liquid supply temperatures is higher than a sum of the preset temperature and a first temperature, and the number of the at least one activated dry cooler is less than a preset number, generate a first control signal for the first variable-frequency driver; so as to control the first variable-frequency driver to gradually increase the frequency of the circulation pump to a target frequency after a delay of a first time, wherein the target frequency is within an upper limit frequency and a lower limit frequency of the circulation pump;
after the frequency of the circulation pump is increased to the upper limit frequency, when the secondary-side liquid supply temperature or the maximum value among the multiple secondary-side liquid supply temperatures is higher than the sum of the preset temperature and the first temperature, generate a second control signal for the second variable-frequency driver, so as to control the second variable-frequency driver to newly activate one of the dry coolers after a delay of a second time.

In a possible implementation, the temperature sensor is also used for collecting a primary-side water temperature of cooling medium water after heat exchange takes place in the radiator, and the heat dissipation controller is further configured to:
when a frequency of a fan of a dry cooler newly activated under control of the second control signal is greater than a preset frequency, and the primary-side water temperature is higher than a sum of the preset temperature and a second temperature, generate a third control signal for the second variable-frequency driver, so as to control the second variable-frequency driver to newly activate one of the dry coolers after a delay of a third time.

In a possible implementation, the heat dissipation controller is further configured to:
based on a water temperature heat dissipation model corresponding to a dry cooler, calculate a frequency of a fan of a newly activated dry cooler by using a PID algorithm, so as to control the second variable-frequency driver through a control signal to adjust the frequency of the fan of the newly activated dry cooler to a frequency calculated by the PID algorithm.

In a possible implementation, the heat dissipation controller is further configured to:
when a difference value resulting from subtracting the secondary-side liquid supply temperature or the maximum value among the multiple secondary-side liquid supply temperatures from the preset temperature is greater than a third temperature and smaller than or equal to a fourth temperature, the number of the at least one activated dry cooler is less than a preset number, and a frequency of a fan of the at least one activated dry cooler is smaller than or equal to a first preset frequency, generate a fourth control signal for the first variable-frequency driver, so as to control the first variable-frequency driver to gradually reduce the frequency of the circulation pump to a target frequency;
when the difference value resulting from subtracting the secondary-side liquid supply temperature or the maximum value among the multiple secondary-side liquid supply temperatures from the preset temperature is greater than the fourth temperature and smaller than or equal to a fifth temperature, and the frequency of the fan of the at least one activated dry cooler is smaller than or equal to a second preset frequency, generate a fifth control signal for the second variable-frequency driver, so as to control the second variable-frequency driver to gradually deactivate the at least one activated dry cooler until the number of the at least one activated dry cooler is one;
when the difference value resulting from subtracting the secondary-side liquid supply temperature or the maximum value among the multiple secondary-side liquid supply temperatures from the preset temperature is greater than the fifth temperature, generate a sixth control signal for the second variable-frequency driver, so as to control the second variable-frequency driver to deactivate all activated dry coolers.

In a possible implementation, the heat dissipation controller is further configured to:
calculate a heat dissipation amount of the radiator by using a PID algorithm combined with a fuzzy control algorithm, based on a difference value between the secondary-side liquid supply temperature or the maximum value among the multiple secondary-side liquid supply temperatures and the preset temperature; and determine the frequency of the circulation pump based on the calculated heat dissipation amount;
when the determined frequency of the circulation pump is smaller than the upper limit frequency and greater than the lower limit frequency, determine that the target frequency is the determined frequency of the circulation pump;
when the determined frequency of the circulation pump is greater than or equal to the upper limit frequency, determine that the target frequency is the upper limit frequency;
when the determined frequency of the circulation pump is smaller than or equal to the lower limit frequency, determine that the target frequency is the lower limit frequency.

In a possible implementation, the heat dissipation control system further includes a liquid leakage sensor, a smoke sensor and a surveillance camera.

The heat dissipation controller is further configured to: determine whether there is an abnormality in the immersion tank and the heat dissipation control system, based on data output from any one of the liquid leakage sensor, the smoke sensor and the surveillance camera, and in a case where there is no abnormality, generate the control signal for the first variable-frequency driver and the second variable-frequency driver based on the difference value between the secondary-side liquid supply temperature and the preset temperature.

According to a second aspect, the present application provides an immersion liquid cooling system, including an immersion tank and a heat dissipation control system provided by any embodiment corresponding to the first aspect of the present application; a cavity of the immersion tank is a closed cavity, so as to enclose a heating element and a coolant within the cavity of the immersion tank, thereby performing heat dissipation for the heating element.

According to a third aspect, the present application provides a heat dissipation control method, where the method is applied to an immersion liquid cooling system, and the immersion liquid cooling system includes an immersion tank, a radiator, a circulating pump, a fan, dry coolers, a temperature sensor, a first variable-frequency driver, and a second variable-frequency driver.

The method includes:
acquiring a secondary-side liquid supply temperature collected by the temperature sensor;
generating a control signal for the first variable-frequency driver and the second variable-frequency driver based on a difference value between the secondary-side liquid supply temperature and a preset temperature; and
based on the control signal for the first variable-frequency driver and the second variable-frequency driver, respectively controlling a frequency of the circulation pump and a frequency of the fan, so as to adjust a flow rate of a coolant flowing into the radiator, and controlling the number of at least one activated dry cooler or a heat dissipation amount of the at least one activated dry cooler.

According to a fourth aspect, the present application provides a computer-readable storage medium. The computer readable storage medium is stored with computer executable instructions, which when executed by a processor, implement a heat dissipation control method provided by any embodiment corresponding to the third aspect.

According to a fifth aspect, the present application provides a computer program product, including a computer program, which when executed by a processor, implements a heat dissipation control method provided by any embodiment corresponding to the third aspect of the present application.

In the heat dissipation control system, the heat dissipation control method and the immersion liquid cooling system provided by the present application, temperature control of the coolant in the immersion tank is implemented through the radiator and the dry coolers. In order to broaden a range of the controllable temperature, a flow rate of the radiator and the number of at least one activated dry cooler or a frequency of the at least one activated dry cooler are controlled through a corresponding variable-frequency driver, based on a difference value between the fed-back secondary-side liquid supply temperature and the preset temperature. The temperature of the coolant in the tank is jointly controlled by control variables from the two dimensions, thus the temperature can be controlled in a wide range, thereby better adapting to a complex environment, and broadening an application range. In addition, the dry coolers are introduced for heat dissipation, thereby saving water resources.

### BRIEF DESCRIPTION OF DRAWINGS

The accompanying drawings here, which are incorporated and form part of the description, illustrate embodiments consistent with the present application and together with the description, serve to explain the principles of the present application.

FIG. 1 is a schematic structural diagram of an immersion liquid cooling system for a server according to an embodiment of the present application.

FIG. 2 is a schematic structural diagram of a heat dissipation control system according to an embodiment of the present application.

FIG. 3 is a schematic structural diagram of another heat dissipation control system according to an embodiment of the present application.

FIG. 4 is a schematic structural diagram of still another heat dissipation control system according to an embodiment of the present application.

FIG. 5 is a schematic structural diagram of still another heat dissipation control system according to an embodiment of the present application.

FIG. 6 is a schematic structural diagram of an immersion liquid cooling system according to an embodiment of the present application.

FIG. 7 is a schematic flowchart of a heat dissipation control method according to an embodiment of the present application.

### REFERENCE SIGNS

10—immersion liquid cooling system;
200—heat dissipation control system; 210—radiator; 220—circulation pump; 230—fan; 240—dry cooler; 250—temperature sensor; 260—first variable-frequency driver; 270—second variable-frequency driver; 280—heat dissipation controller; 281—liquid leakage sensor; 282—smoke sensor; 283—surveillance camera;
100—immersion tank; 110—cavity; 120—heating element.

The accompanying drawings illustrate specific embodiments of the present application, and are described in more detail in the following. The accompanying drawings and the text description are not intended to limit the scope of the technical concept of the present application in any way, but are used to describe the concepts of the present application for those skilled in the art by referring to specific embodiments.

### DESCRIPTION OF EMBODIMENTS

Illustrative embodiments will be described in detail, with examples shown in the accompanying drawings. When the following description involves the accompanying drawings, unless otherwise indicated, the same numbering in different drawings may represent the same or similar elements. The embodiments described in the following illustrative embodiments do not represent all embodiments consistent with the present application. On the contrary, they are merely examples of apparatuses and methods consistent with some aspects of the present application, as described in the appended claims.

Firstly, terms related to the present application are explained.

Immersion liquid cooling: a coolant is used as a heat conducting medium, a heating element is immersed in the coolant, and heat dissipation is performed for the heating element by means of heat exchange.

Primary side: a part responsible for transferring heat from the heating element to a CDU.

Secondary side: a part responsible for transferring the coolant to an immersion tank or the heating element.

Secondary-side liquid supply temperature: a temperature of the coolant transferred to the immersion tank by the CDU.

Primary-side water temperature: a temperature of the cooling medium water discharged after heat exchange of a radiator.

Because of powerful computing capabilities, a server is widely used, for example, in scenarios such as a data center, cloud computing, and a database, etc.

Because the server runs at a high speed and without interruption, more heat is generated, and in order to prevent the performance and service life of the server from being affected by overheat of the server, the server needs to be cooled.

An immersion liquid cooling system is widely applied to cooling of IT (Information Technology) devices, such as servers, due to advantages of high cooling efficiency, low energy consumption, and being applicable to cooling of high-density devices.

A technical solution of the present application and how to solve the above technical problem with the technical solution will be described in detail below with reference to specific embodiments. The following several specific embodiments may be combined with each other, and the same or similar concepts or procedures may not be repeated in certain embodiments. Embodiments of the present application will be described below with reference to the drawings.

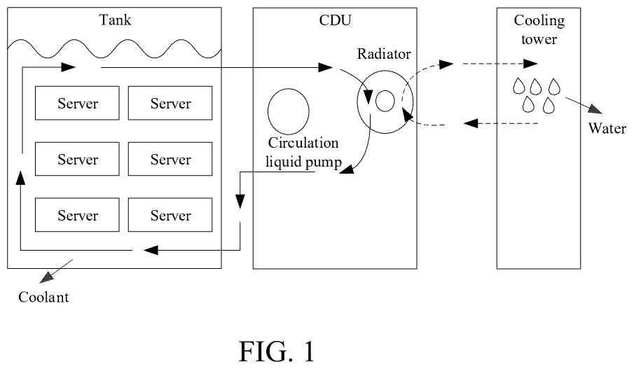

FIG. 1 is a schematic structural diagram of an immersion liquid cooling system for a server according to an embodiment of the present application. As shown in FIG. 1, the immersion liquid cooling system includes an immersion tank, a coolant distribution unit (CDU), and a cooling tower. A cavity of the immersion tank includes a coolant and a server immersed in the coolant. The coolant distribution unit includes a circulation liquid pump and a radiator. The coolant heated by the server flows into the radiator under the drive of the circulation liquid pump for heat dissipation and cooling, and the cooled coolant continues to circulate to the cavity of the immersion tank under the action of the circulation liquid pump for cooling of the server.

The radiator uses water as a cooling medium, the water heated by the radiator flows into the cooling tower for cooling under the action of a circulation water pump (not shown in FIG. 1), and the cooled water flows into the radiator under the action of the circulation water pump, so as to cool the coolant in the radiator.

The radiator is provided with pipelines for circulation of the coolant and water, so that the coolant with a higher temperature is cooled by circulation of water with a lower temperature, the cooled coolant is circulated to the immersion tank, and the heated water is circulated to the cooling tower for cooling.

In the immersion liquid cooling system, circulation of the coolant may be performed through a coolant circulation pipeline (represented by solid lines with arrows in FIG. 1), and circulation of water may be performed through a water circulation pipeline (represented by dotted lines with arrows in FIG. 1).

In some embodiments, the coolant in the immersion tank may be oil, such as mineral oil.

The radiator may include a circulation water chamber and a circulation oil chamber to circulate water and oil, respectively.

In some embodiments, the cooling tower may use a dry cooler to perform water cooling, i.e., the cooling tower is a dry-cooling tower.

The dry cooler is also referred to as a dry-wet cooler, and has almost no water consumption in its working process, thereby reducing water resource consumption.

In the related art, the temperature of the coolant is generally controlled by controlling the heat exchange amount of the CDU, thereby achieving the control of the operating temperature of the server. By controlling only a single variable, a temperature adjustment range is narrow and it cannot be applied to a complex environment.

In order to improve the range and accuracy of temperature control of the coolant in the immersion liquid cooling system, an embodiment of the present application provides a heat dissipation control system, which realizes joint control of the temperature of the coolant in the immersion tank based on control of a primary-side flow rate of the radiator and a frequency of a fan of a dry-cooling tower. The temperature adjustable range is wide, and environment adaptability is strong. In addition, the dry-cooling tower is used for heat dissipation, thereby saving water resources.

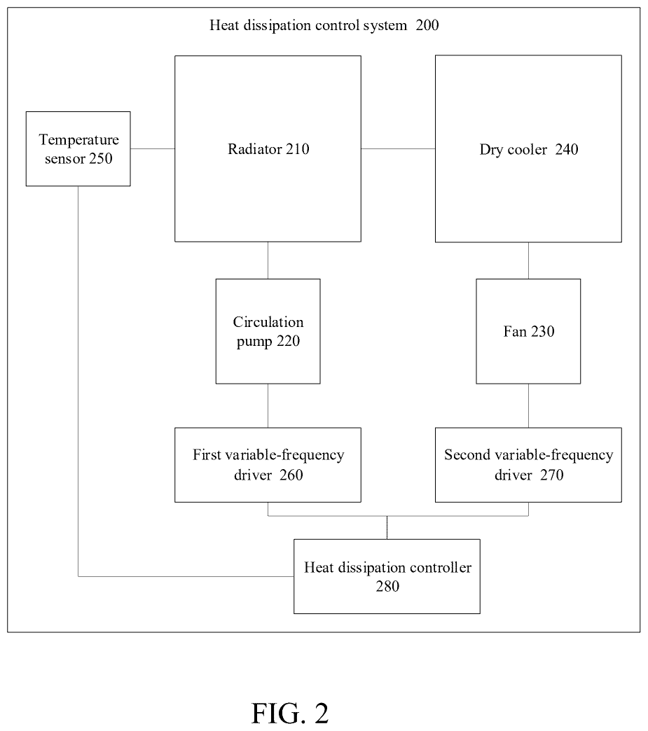

FIG. 2 is a schematic structural diagram of a heat dissipation control system according to an embodiment of the present application. The heat dissipation control system is applied to an immersion liquid cooling system. For a scenario of temperature control for a coolant in the immersion liquid cooling system, as shown in FIG. 2, the heat dissipation control system 200 includes: a radiator 210, a circulation pump 220, a fan 230, a dry cooler 240, a temperature sensor 250, a first variable-frequency driver 260, a second variable-frequency driver 270, and a heat dissipation controller 280.

The connection relationship between modules in FIG. 2 may indicate an electrical connection or a connection through a pipeline.

The coolant heated by a heating element in an immersion tank exchanges heat with a cooling medium such as water in the radiator 210 through the radiator 210 and is cooled, and the cooled coolant flows into the immersion tank under the drive of the circulation pump 220 to perform heat dissipation for the heating element. The dry cooler 240 is used for performing heat dissipation for the cooling medium of the radiator.

The circulation pump 220 is a variable-frequency water pump, and an output flow rate of the circulation pump is adjusted by changing an input frequency.

The first variable-frequency driver 260 is used for adjusting a frequency of the circulation pump 220, so as to adjust a flow rate of the coolant flowing into the radiator 210, thereby adjusting a heat dissipation amount of the radiator 210.

There may be a plurality of dry coolers 240. A rotation speed of the fan 230 may be adjusted by controlling a frequency of the fan 230, so as to change an air volume of the fan 230, thereby adjusting a heat dissipation amount of the dry coolers 240. The frequency of the fan 230 is adjusted by the second variable-frequency driver 270.

The second variable-frequency driver 270 is also used for activating or deactivating at least one of the dry coolers 240 based on a control signal input by the heat dissipation controller 280, so as to adjust the number of at least one activated dry cooler 240.

In some embodiments, the dry cooler 240 may be a dry-cooling tower. The radiator 210 may be a plate radiator.

The temperature sensor 250 is used for collecting a secondary-side liquid supply temperature, where the secondary-side liquid supply temperature is a temperature of the coolant flowing into the immersion tank.

In some embodiments, the temperature sensor 250 may be disposed in a pipe connecting a coolant outlet of the radiator and a coolant inlet of the immersion tank.

The heat dissipation controller 280 is used for generating a control signal for the first variable-frequency driver 260 and the second variable-frequency driver 270 based on a difference value between the secondary-side liquid supply temperature and a preset temperature. The first variable-frequency driver 260 is used for controlling a frequency of the circulation pump 220 based on an input control signal, so as to adjust a flow rate of the coolant flowing into the radiator 210. The second variable-frequency driver 270 is used for controlling a frequency of the fan 230 based on an input control signal, so as to newly activate one or more of the dry coolers 240 or adjust a heat dissipation amount of the activated dry coolers 240.

The preset temperature may be manually set by means of operating the touch screen, or may be remotely set by means of communicating with a remote device.

Illustratively, the preset temperature may be 40° C., 45° C., 50° C., 55° C., or other temperatures.

The heat dissipation controller 280 may be disposed in a control cabinet, and generates the control signal for the first variable-frequency driver 260 and the second variable-frequency driver 270 by regularly or irregularly acquiring the secondary-side liquid supply temperature collected by the temperature sensor 250.

In some embodiments, the heat dissipation controller 280 may generate a control signal for the first variable frequency driver 260, based on a difference value between a current secondary-side liquid supply temperature and a preset temperature, using a PID (Proportional Integral Derivative) algorithm in combination with a fuzzy algorithm, and generate a control signal for the second variable-frequency driver 270, based on a difference value between the current secondary-side liquid supply temperature and the preset temperature using a PID algorithm.

An upper limit frequency and a lower limit frequency of the circulation pump may also be set, so that the first variable-frequency driver 260 controls the frequency of the circulation pump 220 within the upper limit frequency and the lower limit frequency based on an input control signal.

In the heat dissipation control system 200 provided by this embodiment, the temperature of the coolant in the immersion tank is controlled by the radiator 210 and the dry coolers 240. In order to broaden the range of the controllable temperature, the flow rate of the radiator 210 and the number of dry coolers 240 to be activated or the operating frequency of the dry coolers are controlled through a corresponding variable-frequency driver, based on the difference value between the fed-back secondary-side liquid supply temperature and the preset temperature. The temperature of the coolant in the tank is jointly controlled by control variables from the two dimensions, thus the temperature can be controlled in a wide range, thereby better adapting to a complex environment, and broadening the application range. In addition, the dry coolers are introduced for heat dissipation, thereby saving water resources.

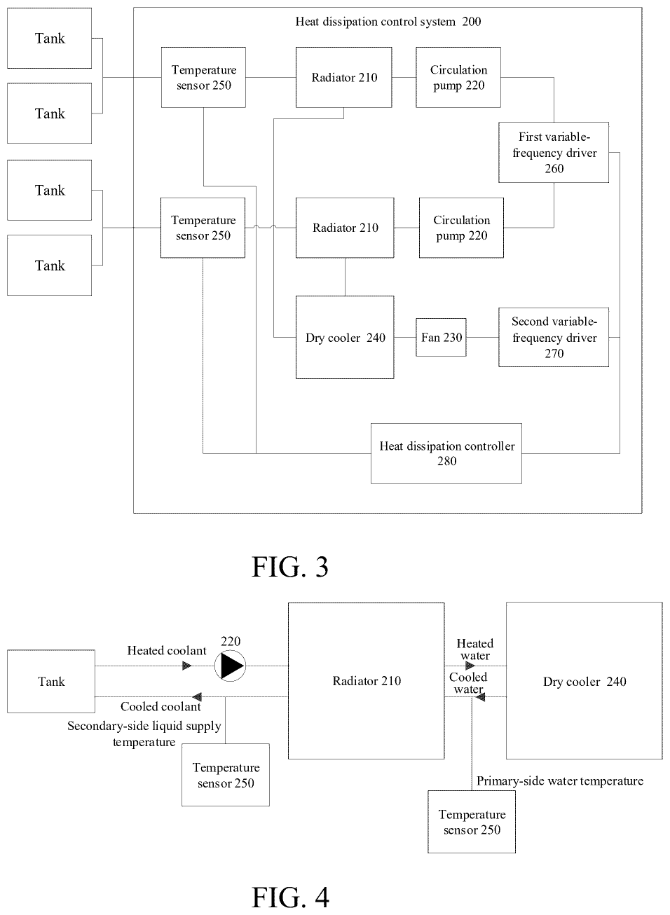

FIG. 3 is a schematic structural diagram of another heat dissipation control system according to an embodiment of the present application. Referring to FIGS. 2 and 3, in this embodiment, there are multiple temperature sensors 250.

The immersion tanks are divided into a plurality of groups, and FIG. 3 takes two groups of immersion tanks and two immersion tanks included in each group as an example.

Different temperature sensors 250 are responsible for collecting secondary-side liquid supply temperatures fed back by different groups of immersion tanks. Different groups of the immersion tanks may be dissipated by different radiators 210, and one radiator 210 corresponds to one circulation pump 220.

The immersion tank includes multiple layers, each of which can house multiple heating elements, such as servers or other electronic devices.

The heat dissipation controller 280 is specifically configured to generate the control signal for the first variable-frequency driver 260 and the second variable-frequency driver 270, based on a difference value between a maximum value among the secondary-side liquid supply temperatures collected by the multiple temperature sensors 250 and the preset temperature.

In some embodiments, the immersion tanks and the CDU (including the radiator 210 and the circulation pump 220) may be disposed indoors, while the dry coolers 240 and the fan 230 may be disposed outdoors, so as to take advantage of convection in a natural environment to cool a cooling medium, such as water.

In other embodiments, the maximum value among multiple secondary-side liquid supply temperatures may be replaced with an average value of the multiple secondary-side liquid supply temperatures.

In a possible implementation, the heat dissipation controller 280 is specifically configured to:
when the secondary-side liquid supply temperature or the maximum value among the multiple secondary-side liquid supply temperatures is higher than a sum of the preset temperature and a first temperature, and the number of the at least one activated dry cooler 240 is less than a preset number, generate a first control signal for the first variable-frequency driver 260, so as to control the first variable-frequency driver 260 to gradually increase the frequency of the circulation pump 220 to a target frequency after a delay of a first time, where the target frequency is within an upper limit frequency and a lower limit frequency of the circulation pump 220; after the frequency of the circulation pump 220 is increased to the upper limit frequency, when the secondary-side liquid supply temperature or the maximum value among the multiple secondary-side supply temperatures is still higher than the sum of the preset temperature and the first temperature, generate a second control signal for the second variable-frequency driver 270, so as to control the second variable-frequency driver 270 to newly activate one of the dry coolers 240 after a delay of a second time.

The multiple secondary-side liquid supply temperatures are respectively collected by multiple temperature sensors 250.

When the fed-back secondary-side liquid supply temperature or the maximum value thereof is greater than the sum of the preset temperature T0 and the first temperature ΔT1, that is, T_{FB}>(T0+ΔT1), where T_{FB} is the secondary-side liquid supply temperature or the maximum value among the multiple secondary-side liquid supply temperatures, and the number NR of the at least one activated dry cooler 240 is less than a preset number N1, after the delay of the first time, the frequency of the circulation pump 220 is gradually increased until reaching the target frequency through the heat dissipation controller 280 and the first variable-frequency driver 260. Thus, the flow rate of the coolant flowing into the immersion tank is increased.

Illustratively, the first temperature ΔT1 may be 0.5° C., 1° C., 1.5° C., or other relatively low temperatures, and the preset number N1 may be 1, 2, 3, or other relatively small values.

The first temperature ΔT1, the preset number N1, and some parameters provided in subsequent embodiments are all configurable parameters, and may be adjusted or configured based on characteristics of the built immersion liquid cooling system.

The target frequency may be calculated based on a difference value between the fed-back temperature, that is, T_{F}B and the preset temperature T0, by using a control algorithm, such as a PID algorithm, an adaptive PID algorithm, a fuzzy algorithm, a PID algorithm in combination with a fuzzy algorithm, etc.

Specifically, when T_{FB}>(T0+ΔT1), the heat dissipation controller 280 determines the target frequency of the circulation pump 220 based on the difference value between T_{FB} and T0, by adopting a PID algorithm combined with a fuzzy algorithm, and generates a first control signal for the first variable-frequency driver 260 based on the target frequency, so that based on the input first control signal, the first variable-frequency driver 260, after the delay of the first time, gradually increases the frequency of the circulation pump 220 to a determined target frequency. For example, the frequency of the circulation pump 220 is linearly increased to the determined target frequency.

In some embodiments, when the determined target frequency is greater than the upper limit frequency of the circulation pump 220, the target frequency is adjusted to be the upper limit frequency of the circulation pump 220.

When the target frequency is smaller than the upper limit frequency of the circulation pump 220, and after the frequency of the circulation pump 220 is increased to the target frequency, if the currently fed-back temperature, that is, T_{FB}, still satisfies T_{FB}>(T0+ΔT1), a control signal, e.g., a seventh control signal, for the first variable-frequency driver 260 may be generated, so as to gradually increase the frequency of the circulation pump 220 from the target frequency to the upper limit frequency of the circulation pump 220 via the first variable-frequency driver 260 after a delay of a few seconds, e.g., the first time.

After the frequency of the circulation pump 220 is increased to the corresponding upper limit frequency (e.g., 50 Hz), if the currently fed-back temperature, i.e., T_{FB}, still satisfies T_{FB}>(T0+ΔT1), that is, the currently collected secondary-side liquid supply temperature or the maximum value among the multiple secondary-side liquid supply temperatures is higher than the sum of the preset temperature and the first temperature, a second control signal for the second variable-frequency driver 270 is generated, so that the second variable-frequency driver 270 is controlled by means of the second control signal to newly activate one of the dry coolers 240 after a delay of a second time. Cooling of the cooling medium water in the radiator 210 is accelerated by increasing the number of the at least one activated dry cooler 240, thereby achieving the purpose of lowering the temperature of the coolant such as oil.

In some embodiments, the second time is larger than the first time, such as twice the first time.

Illustratively, the first time may be 5 s, and the second time is 10 s.

Further, the heat dissipation controller 280 may also determine, by using a PID algorithm and based on a difference value between a currently fed-back temperature T_{FB} and a preset temperature T0, a frequency of a newly activated dry cooler 240, so as to control, by using a corresponding control signal, such as the second control signal, the second variable-frequency driver 270 to newly activate one of the dry coolers 240, and gradually increase a frequency of the newly activated dry cooler 240 to the determined frequency.

In this embodiment, in a case that the fed-back temperature is higher than the preset temperature by at least the first temperature, the temperature is adjusted by firstly increasing the frequency of the circulation pump 220, and if a difference value between the fed-back temperature after adjustment and the preset temperature is smaller than the first temperature, the control target is reached. If the fed-back temperature after the adjustment is still higher than the preset temperature by at least the first temperature, the temperature is adjusted by means of adding a dry cooler 240. In this way, a control manner of firstly adjusting the flow rate of the radiator 210 and then adjusting the heat dissipation amount of the dry coolers 240 is implemented, thereby achieving a wide temperature adjustable range and achieving the objective of saving energy.

FIG. 4 is a schematic structural diagram of still another heat dissipation control system according to an embodiment of the present application. In conjunction with FIGS. 3 and 4, it can be seen that, in this embodiment, the temperature sensor 250 is also used for collecting a primary-side water temperature of the cooling medium water after heat exchange takes place in the radiator 210. The primary-side water temperature is a temperature of the cooling medium water flowing into the radiator 210.

The heat dissipation controller 280 is further configured to generate a third control signal for the second variable-frequency driver 270, when a frequency of a fan 230 of a dry cooler 240 newly activated under the control of the second control signal is greater than a preset frequency and the primary-side water temperature is higher than a sum of the preset temperature and a second temperature, so as to control the second variable-frequency driver 270 to newly activate one of the dry coolers 240 after a delay of a third time.

The preset frequency is a configurable parameter. Illustratively, the preset frequency may be 45 Hz, 50 Hz, or other frequencies, and may be the upper limit frequency of the dry cooler 240.

The second temperature is a configurable parameter. Illustratively, the second temperature may be 0.5° C., 1° C., 1.5° C., or other temperatures.

In some embodiments, the second temperature may be equal to the first temperature.

If the fed-back primary-side water temperature is higher than the sum of the preset temperature and the second temperature after one of the dry coolers 240 is newly activated, the second variable-frequency driver 270 is controlled to continue to newly activate another one of the dry coolers 240 until all the dry coolers 240 are activated or until the primary-side water temperature is lower than or equal to the sum of the preset temperature and the second temperature.

A frequency of the newly activated dry cooler 240 may also be controlled by the heat dissipation controller 280. The heat dissipation controller 280 may calculate, based on a difference value between the primary-side water temperature and the preset temperature, the frequency of the newly activated dry cooler 240, according to a water temperature heat dissipation model by using the PID algorithm.

In a possible implementation, the heat dissipation controller 280 is further configured to:
based on a water temperature heat dissipation model corresponding to a dry cooler 240, calculate a frequency of a fan 230 of a newly activated dry cooler 240 by using a PID algorithm, so as to control the second variable-frequency driver 270 through a control signal (a second control signal or a third control signal) to adjust the frequency of the fan 230 of the newly activated dry cooler 240 to a frequency calculated by the PID algorithm.

When the ambient temperature is low, the running load of the server is light, the flow rate of the circulating pump 220 is high, or in other cases, a situation that the secondary-side liquid supply temperature is lower than a preset temperature may occur. In order to reduce power consumption, when the secondary-side liquid supply temperature is lower than a difference value between the preset temperature and a third temperature, through the first variable-frequency driver 260 and the second variable-frequency driver 270, the heat dissipation controller 280 may reduce the frequency of the circulation pump 220, thereby reducing the primary-side flow rate of the radiator 210, and may reduce the rotation speed of the fan 230 or the number of the at least one activated dry cooler 240, thereby reducing the heat dissipation amount of the dry coolers 240.

In a possible implementation, the heat dissipation controller 280 is further configured to:
when a difference value resulting from subtracting the secondary-side liquid supply temperature or a maximum value among multiple secondary-side liquid supply temperatures from the preset temperature is greater than a third temperature ΔT3 and smaller than or equal to a fourth temperature ΔT4, the number of the at least one activated dry cooler 240 is less than a preset number, and a frequency of a fan of the at least one activated dry cooler 240 is smaller than or equal to a first preset frequency, generate a fourth control signal for the first variable-frequency driver 260, so as to control the first variable-frequency driver 260 to gradually reduce the frequency of the circulation pump 220 to a target frequency;
when the difference value resulting from subtracting the secondary-side liquid supply temperature or the maximum value among the multiple secondary-side liquid supply temperatures from the preset temperature is greater than the fourth temperature ΔT4 and smaller than or equal to a fifth temperature ΔT5, and the frequency of the fan of the at least one activated dry cooler 240 is smaller than or equal to a second preset frequency, generate a fifth control signal for the second variable-frequency driver 270, so as to control the second variable-frequency driver 270 to gradually deactivate the at least one activated dry cooler 240 until the number of the at least one activated dry cooler 240 is one;
when the difference value resulting from subtracting the secondary-side liquid supply temperature or the maximum value among the multiple secondary-side liquid supply temperatures from the preset temperature is greater than the fifth temperature ΔT5, generate a sixth control signal for the second variable-frequency driver 270, so as to control the second variable-frequency driver 270 to deactivate all activated dry coolers 240.

The third to the fifth temperatures are all configurable parameters. Illustratively, the third temperature may be 1° C., the fourth temperature may be 5° C., and the fifth temperature may be 10° C.

When (T0−ΔT4)≤T_{FB}<(T0−ΔT3), it is determined whether the number of the at least one activated dry cooler 240 is less than a preset number and whether the frequency of the at least one activated dry cooler 240 is smaller than or equal to the first preset frequency, such as 30 Hz, and if both are yes, the heat dissipation controller 280 controls, through the fourth control signal, the first variable-frequency driver 260 to gradually reduce the frequency of the circulation pump 220 to a target frequency.

The target frequency may be calculated by using a PID algorithm in combination with a fuzzy algorithm based on a difference value between TO and T_{FB}.

In some embodiments, the target frequency corresponding to the fourth control signal may be the lower limit frequency of the circulation pump 220.

Illustratively, the preset number may be 2. In a case that (T0−ΔT4)≤T_{FB}<(T0−ΔT3), only one of the dry coolers 240 is activated and the operating frequency is smaller than the first preset frequency, the heat dissipation controller 280 controls the first variable-frequency driver 260 to gradually reduce the frequency of the circulation pump 220 to the target frequency.

When the target frequency corresponding to the fourth control signal is greater than the lower limit frequency of the circulation pump 220, after the frequency of the circulation pump 220 is reduced to the target frequency based on the fourth control signal, if the currently fed-back temperature, i.e., T_{FB}, still satisfies (T0−ΔT4)≤T_{FB}<T0−ΔT3), the heat dissipation controller 280 controls the first frequency-variable driver 260 to gradually reduce the frequency of the circulation pump 220 to the lower limit frequency.

When (T0−ΔT5)≤T_{FB}<(T0−ΔT4), it is determined whether there is a fan 230 with a operating frequency smaller than or equal to the second preset frequency, such as 20 Hz, if so, the heat dissipation controller 280 controls, through the fifth control signal, the second variable-frequency driver 270 to deactivate one of the activated dry coolers 240, and after a delay of a period of time, such as 20 s, gradually deactivate other activated dry coolers 240 until only one activated dry cooler 240 remains, or the current fed-back temperature T_{FB} does not satisfy (T0−ΔT5)≤T_{FB}<(T0−ΔT4).

The second preset frequency is smaller than the first preset frequency.

In some embodiments, the second preset frequency is the lower limit frequency of fan 230.

The frequency of the activated dry cooler 240 may be calculated by the heat dissipation controller 280 based on a difference value between T_{FB} and T0, by using a PID algorithm and a water temperature heat dissipation model, and is controlled by the second variable-frequency driver 270.

When T_{FB}<(T0−ΔT5), if an activated dry cooler 240 exists, the heat dissipation controller 280 controls, through the sixth control signal, the second variable-frequency driver 270 to deactivate all activated dry coolers 240, so that the heat dissipation of the coolant in the immersion tank is performed only through the radiator 210.

The deactivation of the activated dry coolers 240 may be achieved by deactivating the fan 230 of the dry coolers 240 and the circulation pump.

In a possible implementation, the heat dissipation controller 280 is further configured to:
calculate a heat dissipation amount of the radiator 210 by using a PID algorithm combined with a fuzzy control algorithm, based on a difference value between the secondary-side liquid supply temperature or the maximum value among the multiple secondary-side liquid supply temperatures and the preset temperature; and determine the frequency of the circulation pump 220 based on the calculated heat dissipation amount;
when the determined frequency of the circulation pump 220 is smaller than the upper limit frequency and greater than the lower limit frequency, determine that the target frequency is the determined frequency of the circulation pump 220; when the determined frequency of the circulation pump 220 is greater than or equal to the upper limit frequency, determine that the target frequency is the upper limit frequency;
when the determined frequency of the circulation pump 220 is smaller than or equal to the lower limit frequency, determine that the target frequency is the lower limit frequency.

In a case where the fed-back temperature is lower than the preset temperature, the power consumption of the system is reduced by control strategies such as reducing the frequency of the circulation pump 220, reducing the number of the at least one activated dry cooler 240, and the like. Meanwhile, by setting the lower limit frequency of the fan 230, the fan 230 is prevented from being overheated due to running at an excessively low frequency.

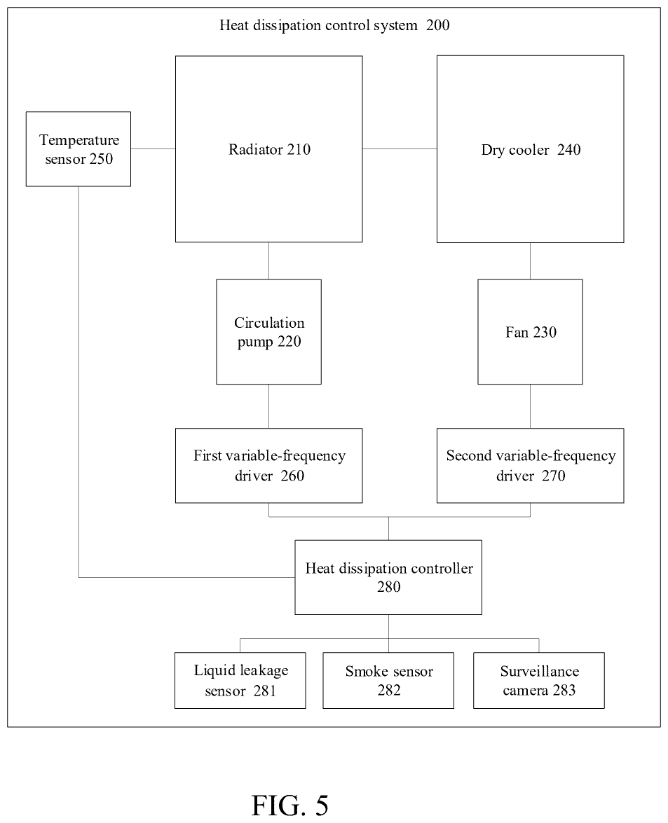

FIG. 5 is a schematic structural diagram of still another heat dissipation control system according to an embodiment of the present application. Referring to FIGS. 2 to 5, in this embodiment, the heat dissipation control system 200 further includes a liquid leakage sensor 281, a smoke sensor 282, and a surveillance camera 283. The heat dissipation controller 280 is further configured to: determine whether there is an abnormality in the immersion tank and the heat dissipation control system 200, based on data output from any one of the liquid leakage sensor 281, the smoke sensor 282, and the surveillance camera 283; and in a case where there is no abnormality, generate the control signal for the first variable-frequency driver 260 and the second variable-frequency driver 270 with the method provided by the foregoing embodiments, that is, based on the difference value between the secondary-side liquid supply temperature and the preset temperature.

There may be multiple liquid leakage sensors 281, which are provided in a pipeline and the immersion tank, so as to detect whether liquid leakage occurs in the pipeline and the immersion tank.

The smoke sensor 282 is configured to detect whether smoke is generated by electrical components of the heat dissipation control system 200.

The surveillance camera 283 is configured to collect images/videos of the heat dissipation control system 200 and the immersion tank, so as to determine, based on the collected images/videos, whether there is an abnormality in the immersion tank and the heat dissipation control system 200, for example, to determine whether there is an external object, a state of a device running indicator lamp, and the like.

Further, the heat dissipation controller 280 is further configured to trigger an abnormality protection mechanism, such as cutting off a power supply and performing an audible and visual pre-warning, when it determines that there is an abnormality in the immersion tank or the heat dissipation control system 200 based on the data output from any one of: the liquid leakage sensor 281, the smoke sensor 282, and the surveillance camera 283.

The deployment of the multi-dimensional sensors improves the operation safety of the heat dissipation control system 200.

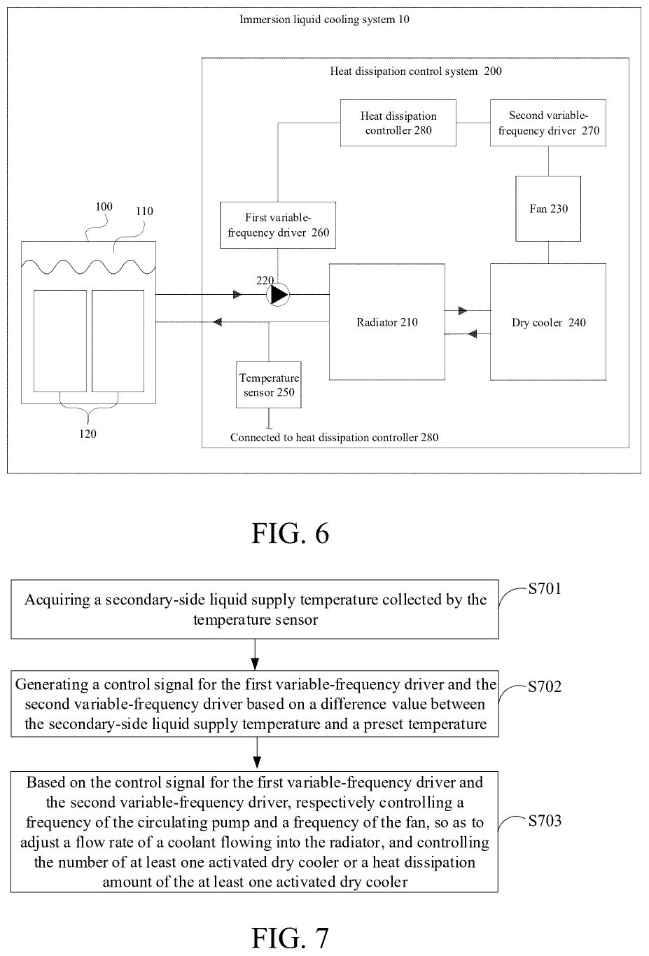

FIG. 6 is a schematic structural diagram of an immersion liquid cooling system according to an embodiment of the present application. As shown in FIG. 6, the immersion liquid cooling system 10 includes an immersion tank 100 and a heat dissipation control system 200 according to any embodiment of the present application.

A cavity 110 of the immersion tank 100 is a closed cavity, so as to enclose a heating element 120 and a coolant within the cavity 110 of the immersion tank 100, thereby performing heat dissipation for the heating element 120. The heating element 120 is an IT device. In FIG. 6, as an example, two heating elements 120 are deployed in the cavity 110 of the immersion tank 100.

Illustratively, the heating element 120 is a server.

The number of immersion tanks 100 may be multiple, and the multiple immersion tanks may be accommodated in one tank, such as a container and a cooling cabinet.

In some embodiments, the immersion tank 100 may include multiple layers, each of which may house multiple heating elements 120.

FIG. 7 is a schematic flowchart of a heat dissipation control method according to an embodiment of the present application. The method is applied to an immersion liquid cooling system. The immersion liquid cooling system includes an immersion tank, a radiator, a circulation pump, a fan, dry coolers, a temperature sensor, a first variable-frequency driver, and a second variable-frequency driver.

The temperature sensor is used for collecting a temperature of the secondary-side liquid supply temperature. The first variable-frequency driver is used for controlling a frequency of the circulation pump so as to adjust a primary-side flow rate of the coolant of the radiator, thereby adjusting the flow rate of the coolant flowing into the immersion tank. The second variable-frequency driver is used for controlling a frequency of a fan of at least one dry cooler, so as to adjust the rotation speed of the fan, thereby realizing the control of the heat dissipation amount of the at least one dry cooler. The second variable-frequency driver is also used for activating or deactivating the at least one dry cooler.

In some embodiments, the immersion liquid cooling system may be the foregoing immersion liquid cooling system 10, and the heat dissipation control method may be executed by the heat dissipation controller 280 of the immersion liquid cooling system 10.

As shown in FIG. 7, the heat dissipation control method includes the following steps.

Step S701, acquiring a secondary-side liquid supply temperature collected by the temperature sensor.

Step S702, generating a control signal for the first variable-frequency driver and the second variable-frequency driver based on a difference value between the secondary-side liquid supply temperature and a preset temperature.

Step S703, based on the control signal for the first variable-frequency driver and the second variable-frequency driver, respectively controlling a frequency of the circulating pump and a frequency of the fan, so as to adjust a flow rate of a coolant flowing into the radiator, and controlling the number of at least one activated dry cooler or a heat dissipation amount of the at least one activated dry cooler.

In a possible implementation, there are multiple temperature sensors, and the generating the control signal for the first variable-frequency driver and the second variable-frequency driver based on the difference value between the secondary-side liquid supply temperature and the preset temperature includes:
generating the control signal for the first variable-frequency driver and the second variable-frequency driver based on a difference value between a maximum value among secondary-side liquid supply temperatures collected by the multiple temperature sensors and the preset temperature.

In a possible implementation, the generating the control signal for the first variable-frequency driver and the second variable-frequency driver based on the difference value between the secondary-side liquid supply temperature and the preset temperature includes:
when the secondary-side liquid supply temperature or a maximum value among multiple secondary-side liquid supply temperatures is higher than a sum of the preset temperature and a first temperature, and the number of the at least one activated dry cooler is less than a preset number, generating a first control signal for the first variable-frequency driver; so as to control the first variable-frequency driver to gradually increase a frequency of the circulation pump to a target frequency after a delay of a first time, wherein the target frequency is within an upper limit frequency and a lower limit frequency of the circulation pump; and
after the frequency of the circulation pump is increased to the upper limit frequency, when the secondary-side liquid supply temperature or the maximum value among the multiple secondary-side liquid supply temperatures is higher than the sum of the preset temperature and the first temperature, generating a second control signal for the second variable-frequency driver, so as to control the second variable-frequency driver to newly activate one of the dry coolers after a delay of a second time.

In a possible implementation, the temperature sensor is also used for collecting a primary-side water temperature of cooling medium water after heat exchange takes place in the radiator, and the method further includes:
when a frequency of a fan of a dry cooler newly activated under control of the second control signal is greater than a preset frequency, and the primary-side water temperature is higher than a sum of the preset temperature and a second temperature, generating a third control signal for the second variable-frequency driver, so as to control the second variable-frequency driver to newly activate one of the dry coolers after a delay of a third time.

In a possible implementation, the method further includes:
based on a water temperature heat dissipation model corresponding to a dry cooler, calculating a frequency of a fan of a newly activated dry cooler by using a PID algorithm, so as to control the second variable-frequency driver through the control signal to adjust the frequency of the fan of the newly activated dry cooler to a frequency calculated by the PID algorithm.

In a possible implementation, the generating the control signal for the first variable-frequency driver and the second variable-frequency driver based on the difference value between the secondary-side liquid supply temperature and the preset temperature includes:
when a difference value resulting from subtracting the secondary-side liquid supply temperature or the maximum value among the multiple secondary-side liquid supply temperatures from the preset temperature is greater than a third temperature and smaller than or equal to a fourth temperature, the number of the at least one activated dry cooler is less than a preset number, and a frequency of a fan of the at least one activated dry cooler is smaller than or equal to a first preset frequency, generating a fourth control signal for the first variable-frequency driver, so as to control the first variable-frequency driver to gradually reduce the frequency of the circulation pump to a target frequency;
when the difference value resulting from subtracting the secondary-side liquid supply temperature or the maximum value among the multiple secondary-side liquid supply temperatures from the preset temperature is greater than the fourth temperature and smaller than or equal to a fifth temperature, and the frequency of the fan of the at least one activated dry cooler is smaller than or equal to a second preset frequency, generating a fifth control signal for the second variable-frequency driver, so as to control the second variable-frequency driver to gradually deactivate the at least one activated dry cooler until the number of the at least one activated dry cooler is one;
when the difference value resulting from subtracting the secondary-side liquid supply temperature or the maximum value among the multiple secondary-side liquid supply temperatures from the preset temperature is greater than the fifth temperature, generating a sixth control signal for the second variable-frequency driver, so as to control the second variable-frequency driver to deactivate all activated dry coolers.

In a possible implementation, the method further includes:
calculating a heat dissipation amount of the radiator by using a PID algorithm combined with a fuzzy control algorithm, based on a difference value between the secondary-side liquid supply temperature or the maximum value among the multiple secondary-side liquid supply temperatures and the preset temperature; and determining the frequency of the circulation pump based on the calculated heat dissipation amount;
when the determined frequency of the circulation pump is smaller than the upper limit frequency and greater than the lower limit frequency, determining that the target frequency is the determined frequency of the circulation pump;
when the determined frequency of the circulation pump is greater than or equal to the upper limit frequency, determining that the target frequency is the upper limit frequency;
when the determined frequency of the circulation pump is smaller than or equal to the lower limit frequency, determining that the target frequency is the lower limit frequency.

In a possible implementation, the immersion liquid cooling system further includes a liquid leakage sensor, a smoke sensor, and a surveillance camera, correspondingly, the method further includes:
determining whether the immersion tank and the heat dissipation control system have an abnormality, based on data output from any one of the liquid leakage sensor, the smoke sensor and the surveillance camera; and in a case where there is no abnormality, generating the control signal for the first variable-frequency driver and the second variable-frequency driver based on the difference value between the secondary-side liquid supply temperature and the preset temperature.

In a possible implementation, when it is determined that there is an abnormality in the immersion tank or the heat dissipation control system, an abnormality protection mechanism is triggered, for example, cutting off a power supply, performing an audible and visual pre-warning, and the like.

Embodiments of the present application provide a computer-readable storage medium. The computer-readable storage medium is stored with computer executable instructions, which when executed by a processor, implement a heat dissipation control method according to the foregoing method embodiments.

The foregoing computer-readable storage medium may be implemented by any type of volatile or non-volatile storage device or a combination thereof, such as a static random-access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic disk, or an optical disk. The readable storage medium may be any available media that can be accessed by a general purpose or special purpose computer.

An exemplary readable storage medium is coupled to a processor such that the processor can read information from the readable storage medium and can write information to the readable storage medium. Certainly, the readable storage medium may also be a component of the processor. The processor and the readable storage medium may be located in an application-specific integrated circuit (Application Specific Integrated Circuit, ASIC for short). Of course, the processor and the readable storage medium may also be present in a device as discrete components.

Embodiments of the present application provide a computer program product, including a computer program, which when executed by a processor, implements a heat dissipation control method provided by any of the described embodiments of the present application.

In the description of the embodiments of the present application, it should be noted that, unless specified or indicated otherwise, the terms “mounted”, “in connection with”, and “connected” should be understood broadly, for example, may be in a fixed connection, may also be in an indirect connection through an intermediate medium, may be internal communication between two elements, or may be an interaction relationship between two elements. A person of ordinary skill in the art may understand specific meanings of the above terms in the embodiments of the present application according to specific situations.

In the description of the present application, it should be understood that the terms such as “center”, “length”, “width”, “thickness”, “top”, “bottom”, “up”, “down”, “left”, “right”, “front”, “back”, “vertical”, “horizontal”, “inner”, “outer”, “axial direction”, “circumferential direction” and the like are used to indicate orientation or position relations based on the orientation or position relations shown in the drawings. It is only for convenience in describing the present application and simplifying the description, rather than indicating or implying that the indicated position or element should have a particular orientation, be in a particular configuration and operation. Therefore, it cannot be understood that the present application is limited thereto.

As described or as implied in the embodiments of the present application, the apparatus or the element should have a specific orientation, be in a particular configuration and operation, it cannot be construed as a limitation of the embodiments of the present application. In the description of the embodiments of the present application, “a plurality of” means two or more than two, unless specified otherwise.

The terms “first”, “second”, “third”, “fourth”, and the like (if any) in the description, claims and the accompanying drawings of the embodiments of the present application are used for distinguishing similar objects, and are not used for describing a specific sequence or order. It should be understood that data used in this manner may be interchanged where appropriate so that the embodiments of the present application described herein can be implemented, for example, in sequences other than those illustrated or described herein.

In addition, the terms “include” and “have”, and any variations thereof, are intended to cover a non-exclusive inclusion, for example, a process, a method, a system, a product, or an apparatus that includes a series of steps or units is not necessarily limited to those steps or units that are expressly listed, but may include other steps or units that are not expressly listed or inherent to such process, method, product, or apparatus.

The term “a plurality of” herein means two or more than two. The term “and/or” herein merely describes an association relationship between associated objects, and indicates that three relationships may exist, for example, A and/or B may indicate three cases: A exists separately, A and B exist simultaneously, and B exists separately. In addition, in this text, the character “/” generally indicates an “or” relationship between the front and back associated objects; while in the formula, the character “/” indicates a “division” relationship between the front and back associated objects.

It should be understood that various numberings involved in the embodiments of the present application are only used for distinguishing objects conveniently, and are not used to limit the scope of the embodiments of the present application.

It should be understood that, in the embodiments of the present application, the sequence numbers of the foregoing process do not imply an execution sequence, and the execution sequence of the process should be determined according to functions and internal logics thereof, which should not constitute any limitation to the implementation process of the embodiments of the present application.

Other embodiments of the present application will be readily apparent to those skilled in the art based on the description and practice of the solution disclosed herein. The present application is intended to cover any variations, uses, or adaptations of the present application, the variations, uses, or adaptations follow the general principles of the present application and include common knowledge or general technical means in the technical field not disclosed in the present application. It is intended that the description and embodiments be considered as only illustrative, with the scope and spirit of the present application being indicated by the claims.

It should be understood that the present application is not limited to the exact structure described above and shown in the drawings, and that various modifications and variations may be made without departing from the scope thereof. The scope of the present application is limited only by the appended claims.

1. A heat dissipation control system, applied to an immersion tank, wherein the heat dissipation control system comprises: a radiator, a circulating pump, a fan, dry coolers, a temperature sensor, a first variable-frequency driver, a second variable-frequency driver, and a heat dissipation controller;
the temperature sensor is configured to collect a secondary-side liquid supply temperature;
the heat dissipation controller is configured to generate a control signal for the first variable-frequency driver and the second variable-frequency driver, based on a difference value between the secondary-side liquid supply temperature and a preset temperature;
the first variable-frequency driver is configured to control a frequency of the circulation pump based on an input control signal, so as to adjust a flow rate of a coolant flowing into the radiator; and
the second variable-frequency driver is configured to activate or deactivate at least one of the dry coolers based on an input control signal, and control a frequency of the fan, so as to adjust the number of at least one activated dry cooler or adjust a heat dissipation amount of the at least one activated dry cooler.

2. The system according to claim 1, wherein there are multiple temperature sensors, and the heat dissipation controller is configured to:
generate the control signal for the first variable-frequency driver and the second variable-frequency driver based on a difference value between a maximum value among secondary-side liquid supply temperatures collected by the multiple temperature sensors and the preset temperature.

3. The system according to claim 1, wherein the heat dissipation controller is configured to:
when the secondary-side liquid supply temperature or a maximum value among multiple secondary-side liquid supply temperatures is higher than a sum of the preset temperature and a first temperature, and the number of the at least one activated dry cooler is less than a preset number, generate a first control signal for the first variable-frequency driver; so as to control the first variable-frequency driver to gradually increase the frequency of the circulation pump to a target frequency after a delay of a first time, wherein the target frequency is within an upper limit frequency and a lower limit frequency of the circulation pump;
after the frequency of the circulation pump is increased to the upper limit frequency, when the secondary-side liquid supply temperature or the maximum value among the multiple secondary-side liquid supply temperatures is higher than the sum of the preset temperature and the first temperature, generate a second control signal for the second variable-frequency driver, so as to control the second variable-frequency driver to newly activate one of the dry coolers after a delay of a second time.

4. The system according to claim 3, wherein the temperature sensor is also configured to collect a primary-side water temperature of cooling medium water after heat exchange takes place in the radiator, and the heat dissipation controller is further configured to:
when a frequency of a fan of a dry cooler newly activated under control of the second control signal is greater than a preset frequency, and the primary-side water temperature is higher than a sum of the preset temperature and a second temperature, generate a third control signal for the second variable-frequency driver, so as to control the second variable-frequency driver to newly activate one of the dry coolers after a delay of a third time.

5. The system according to claim 3, wherein the heat dissipation controller is further configured to:
based on a water temperature heat dissipation model corresponding to a dry cooler, calculate a frequency of a fan of a newly activated dry cooler by using a PID algorithm, so as to control the second variable-frequency driver through a control signal to adjust the frequency of the fan of the newly activated dry cooler to a frequency calculated by the PID algorithm.

6. The system according to claim 3, wherein the heat dissipation controller is further configured to:
when a difference value resulting from subtracting the secondary-side liquid supply temperature or the maximum value among the multiple secondary-side liquid supply temperatures from the preset temperature is greater than a third temperature and smaller than or equal to a fourth temperature, the number of the at least one activated dry cooler is less than a preset number, and a frequency of a fan of the at least one activated dry cooler is smaller than or equal to a first preset frequency, generate a fourth control signal for the first variable-frequency driver, so as to control the first variable-frequency driver to gradually reduce the frequency of the circulation pump to a target frequency;
when the difference value resulting from subtracting the secondary-side liquid supply temperature or the maximum value among the multiple secondary-side liquid supply temperatures from the preset temperature is greater than the fourth temperature and smaller than or equal to a fifth temperature, and the frequency of the fan of the at least one activated dry cooler is smaller than or equal to a second preset frequency, generate a fifth control signal for the second variable-frequency driver, so as to control the second variable-frequency driver to gradually deactivate the at least one activated dry cooler until the number of the at least one activated dry cooler is one;
when the difference value resulting from subtracting the secondary-side liquid supply temperature or the maximum value among the multiple secondary-side liquid supply temperatures from the preset temperature is greater than the fifth temperature, generate a sixth control signal for the second variable-frequency driver, so as to control the second variable-frequency driver to deactivate all activated dry coolers.

7. The system according to claim 6, wherein the heat dissipation controller is further configured to:
calculate a heat dissipation amount of the radiator by using a PID algorithm combined with a fuzzy control algorithm, based on a difference value between the secondary-side liquid supply temperature or the maximum value among the multiple secondary-side liquid supply temperatures and the preset temperature; and determine the frequency of the circulation pump based on the calculated heat dissipation amount;
when the determined frequency of the circulation pump is smaller than the upper limit frequency and greater than the lower limit frequency, determine that the target frequency is the determined frequency of the circulation pump;
when the determined frequency of the circulation pump is greater than or equal to the upper limit frequency, determine that the target frequency is the upper limit frequency;
when the determined frequency of the circulation pump is smaller than or equal to the lower limit frequency, determine that the target frequency is the lower limit frequency.

8. The system according to claim 4, further comprising a liquid leakage sensor, a smoke sensor, and a surveillance camera;
the heat dissipation controller is further configured to: determine whether there is an abnormality in the immersion tank and the heat dissipation control system, based on data output from any one of the liquid leakage sensor, the smoke sensor and the surveillance camera; and in a case where there is no abnormality, generate the control signal for the first variable-frequency driver and the second variable-frequency driver based on the difference value between the secondary-side liquid supply temperature and the preset temperature.

9. An immersion liquid cooling system, comprising an immersion tank and the heat dissipation control system according to claim 1;
a cavity of the immersion tank is a closed cavity, so as to enclose a heating element and a coolant within the cavity of the immersion tank, thereby performing heat dissipation for the heating element.

10. A heat dissipation control method, wherein the method is applied to an immersion liquid cooling system, and the immersion liquid cooling system comprises an immersion tank, a radiator, a circulating pump, a fan, dry coolers, a temperature sensor, a first variable-frequency driver, and a second variable-frequency driver; wherein the method comprises:
acquiring a secondary-side liquid supply temperature collected by the temperature sensor;
generating a control signal for the first variable-frequency driver and the second variable-frequency driver based on a difference value between the secondary-side liquid supply temperature and a preset temperature; and
based on the control signal for the first variable-frequency driver and the second variable-frequency driver, respectively controlling a frequency of the circulation pump and a frequency of the fan, so as to adjust a flow rate of a coolant flowing into the radiator, and controlling the number of at least one activated dry cooler or a heat dissipation amount of the at least one activated dry cooler.

11. The method according to claim 10, wherein there are multiple temperature sensors, and the generating the control signal for the first variable-frequency driver and the second variable-frequency driver based on the difference value between the secondary-side liquid supply temperature and the preset temperature comprises:
generating the control signal for the first variable-frequency driver and the second variable-frequency driver based on a difference value between a maximum value among secondary-side liquid supply temperatures collected by the multiple temperature sensors and the preset temperature.

12. The method according to claim 10, wherein the generating the control signal for the first variable-frequency driver and the second variable-frequency driver based on the difference value between the secondary-side liquid supply temperature and the preset temperature comprises:
when the secondary-side liquid supply temperature or a maximum value among multiple secondary-side liquid supply temperatures is higher than a sum of the preset temperature and a first temperature, and the number of the at least one activated dry cooler is less than a preset number, generating a first control signal for the first variable-frequency driver; so as to control the first variable-frequency driver to gradually increase a frequency of the circulation pump to a target frequency after a delay of a first time, wherein the target frequency is within an upper limit frequency and a lower limit frequency of the circulation pump; and
after the frequency of the circulation pump is increased to the upper limit frequency, when the secondary-side liquid supply temperature or the maximum value among the multiple secondary-side liquid supply temperatures is higher than the sum of the preset temperature and the first temperature, generating a second control signal for the second variable-frequency driver, so as to control the second variable-frequency driver to newly activate one of the dry coolers after a delay of a second time.

13. The method according to claim 12, wherein the temperature sensor is also configured to collect a primary-side water temperature of cooling medium water after heat exchange takes place in the radiator, and the method further comprises:
when a frequency of a fan of a dry cooler newly activated under control of the second control signal is greater than a preset frequency, and the primary-side water temperature is higher than a sum of the preset temperature and a second temperature, generating a third control signal for the second variable-frequency driver, so as to control the second variable-frequency driver to newly activate one of the dry coolers after a delay of a third time.

14. The method according to claim 12, wherein the method further comprises:
based on a water temperature heat dissipation model corresponding to a dry cooler, calculating a frequency of a fan of a newly activated dry cooler by using a PID algorithm, so as to control the second variable-frequency driver through the control signal to adjust the frequency of the fan of the newly activated dry cooler to a frequency calculated by the PID algorithm.

15. The method according to claim 12, wherein the generating the control signal for the first variable-frequency driver and the second variable-frequency driver based on the difference value between the secondary-side liquid supply temperature and the preset temperature comprises:
when a difference value resulting from subtracting the secondary-side liquid supply temperature or the maximum value among the multiple secondary-side liquid supply temperatures from the preset temperature is greater than a third temperature and smaller than or equal to a fourth temperature, the number of the at least one activated dry cooler is less than a preset number, and a frequency of a fan of the at least one activated dry cooler is smaller than or equal to a first preset frequency, generating a fourth control signal for the first variable-frequency driver, so as to control the first variable-frequency driver to gradually reduce the frequency of the circulation pump to a target frequency;
when the difference value resulting from subtracting the secondary-side liquid supply temperature or the maximum value among the multiple secondary-side liquid supply temperatures from the preset temperature is greater than the fourth temperature and smaller than or equal to a fifth temperature, and the frequency of the fan of the at least one activated dry cooler is smaller than or equal to a second preset frequency, generating a fifth control signal for the second variable-frequency driver, so as to control the second variable-frequency driver to gradually deactivate the at least one activated dry cooler until the number of the at least one activated dry cooler is one;
when the difference value resulting from subtracting the secondary-side liquid supply temperature or the maximum value among the multiple secondary-side liquid supply temperatures from the preset temperature is greater than the fifth temperature, generating a sixth control signal for the second variable-frequency driver, so as to control the second variable-frequency driver to deactivate all activated dry coolers.

16. The method according to claim 15, wherein the method further comprises:
calculating a heat dissipation amount of the radiator by using a PID algorithm combined with a fuzzy control algorithm, based on a difference value between the secondary-side liquid supply temperature or the maximum value among the multiple secondary-side liquid supply temperatures and the preset temperature; and determining the frequency of the circulation pump based on the calculated heat dissipation amount;
when the determined frequency of the circulation pump is smaller than the upper limit frequency and greater than the lower limit frequency, determining that the target frequency is the determined frequency of the circulation pump;
when the determined frequency of the circulation pump is greater than or equal to the upper limit frequency, determining that the target frequency is the upper limit frequency;
when the determined frequency of the circulation pump is smaller than or equal to the lower limit frequency, determining that the target frequency is the lower limit frequency.

17. The method according to claim 16, wherein the immersion liquid cooling system further includes a liquid leakage sensor, a smoke sensor, and a surveillance camera, correspondingly, the method further comprises:
determining whether there is an abnormality in the immersion tank and the heat dissipation control system, based on data output from any one of the liquid leakage sensor, the smoke sensor and the surveillance camera; and in a case where there is no abnormality, generating the control signal for the first variable-frequency driver and the second variable-frequency driver based on the difference value between the secondary-side liquid supply temperature and the preset temperature.

18. The method according to claim 17, wherein when it is determined that there is an abnormality in the immersion tank or the heat dissipation control system, an abnormality protection mechanism is triggered.
